(19) United States
(12) Patent Application Publication
(10) Pub. No.: US 2005/0136686 A1
(43) Pub. Date: Jun. 23, 2005

(54) Gap-fill method using high density plasma chemical vapor deposition process and method of manufacturing integrated circuit device

(76) Inventors: Do-Hyung Kim, Seoul (KR); Hyeon-Deok Lee, Seoul (KR); Ju-Bum Lee, Gyeonggi-do (KR)

Correspondence Address: MARGER JOHNSON & MCCOLLOM, P.C., 1030 SW MORRISON STREET, PORTLAND, OR, 97205, US

(21) Appl. No.: 11/015,095

(22) Filed: Dec. 16, 2004

(30) Foreign Application Priority Data
Dec. 17, 2003 (KR) 2003-92562

(51) Int. Cl. H01L 21/76; H01L 21/469

(52) U.S. Cl. 438/778; 438/788

(57) ABSTRACT

A method of filling gaps in an integrated circuit device is provided, that is less likely to fill voids and does not cause a lung defect. In one embodiment, a method of manufacturing an integrated circuit device including the gap filling method includes: etching a predetermined area of an integrated circuit device to form a trench, filling the trench with a high density plasma oxide by performing an HDP-CVD process using a first process gas including comprising a gas containing an element from the fluorine group, silane gas, and oxygen to form a high density plasma oxide layer, and plasma treating the integrated circuit substrate with a second process gas including a hydrogen gas or hydrogen and oxygen gases.

This application claims priority from Korean Patent Application No. 2003-92562, filed on Dec. 17, 2003, the disclosure of which is incorporated herein by reference in its entirety.

### BACKGROUND OF THE INVENTION

1. Field of the Invention

The present invention relates to a method of manufacturing an integrated circuit device, and more particularly, to a gap-fill method using a high density plasma chemical vapor deposition (HDP-CVD) process and a method of manufacturing an integrated circuit device.

2. Description of the Related Art

Scaling down the pattern of an integrated circuit device is necessary for higher performance and higher integration. However, when the pattern is scaled down, an aspect ratio of gaps present between adjacent structures increases. As a result, it is more difficult to completely fill the inside of a gap without causing a void. Throughout the specification, the term “gap” refers to a recess present between two adjacent structures, for example, a trench for shallow trench isolation (STI) or a space defined by sidewalls of adjacent gate line structures.

One of the deposition processes with a high gap-fill characteristic is a high density plasma chemical vapor deposition (HDP-CVD) process. The HDP-CVD process is carried out by generating a high-density plasma within a chamber, and then by depositing a predetermined material layer on a substrate to be treated. Since the deposition and sputtering of the material layer are simultaneously carried out in the HDP-CVD process, the gap-fill characteristic is relatively good. Furthermore, the HDP-CVD process has the advantages of low thermal budget and low wet etch rate of HDP oxide layer formed by the HDP-CVD process. Thus, the HDP-CVD process is widely used in a process of filling a gap having a high aspect ratio, such as the trench for STI in an integrated circuit device, of which design rule is about 0.17 μm or less.

In the conventional process of depositing an HDP oxide layer, for example, silane (SiH₄) and oxygen (O₂) are used as a source gas and argon (Ar) is used as a carrier gas. However, as patterns have been further scaled down, this process has become inadequate. When an argon gas has been used as a carrier gas in the HDP-CVD process to fill, for example, a gap of which width and aspect ratio are 0.15 μm and 4.5 or more, respectively, it has not been easy to completely fill the gap without causing a void. The above limitation in the gap-fill characteristic of the HDP-CVD process is caused by the redeposition by sputtering. During redeposition, a sputtered material layer is stacked on an unsputtered opposite wall of a gap. If redeposition occurs excessively, the entrance of the gap may be closed by the redeposited material layer before completely filling the gap, which produces voids in the filled material layer.

One approach to overcome this limitation has been to use a gas having low atomic weight as a carrier gas. Another approach has been to carry out wet etch back after an HDP-CVD process. In the former method, argon gas as a carrier gas has typically not been used alone, but has been used in combination with helium (He) and/or hydrogen (H₂). In this method, the redeposition rate has been decreased due to the low molecular weight of the carrier gas, allowing for fewer voids caused by redeposition. In the latter method, the redeposited layer can be partially removed by wet etch back to improve the gap-fill characteristic. However, both methods increase processing time and manufacturing cost. As a result, it is difficult to apply them to mass production.

Another approach to overcome the limitation in the gap-fill characteristic of an HDP-CVD process has been to add a chemical etch gas to the carrier gas. Nitrogen trifluoride (NF₃) has been used as the chemical etch gas. In this method, the amount of the deposited HDP oxide layer which is chemically etched by the chemical etch gas, increases, whereas the amount of deposited HDP oxide layer which is physically etched by sputtering decreases. Thus, using this method, redeposition can be inhibited so that the gap-fill characteristic is improved and the chance of creating voids is lowered.

However, the method using chemical etch gas has a disadvantage in that a so-called lung defect can occur. When a lung defect is created, an impurity gas remains in a gap-fill insulating layer, deteriorating the layer quality. Since nitrogen trifluoride is used in the HDP-CVD process, the resulting HDP oxide layer develops silicon-fluorine bonds.

FIG. 1A is an SEM photograph showing a lung defect represented by a dotted circle. If a lung defect occurs, a dent or groove is generated on the surface of the HDP oxide layer by a subsequent wet etching or rinsing process because the wet etch rate in the part of the redeposited HDP oxide layer containing a fluorine group is higher than the rest of the sidewalls.

FIG. 1B shows a dent generated by the lung defect. Referring to FIG. 1B, a plurality of trenches are formed on a semiconductor substrate 10. A pad oxide layer 20 and a liner nitride layer 22 are sequentially formed on the inner wall of the trench. On the liner nitride layer 22, an HDP oxide layer 30a filling the trench is formed. According to the conventional STI process, dents are mainly generated on sidewalls of the deposited HDP oxide layer 30a.

Therefore, an HDP-CVD process that has an improved gap-fill characteristic and prevents a lung defect from occurring is required. Embodiments of the invention address these and other limitations in the prior art.

### SUMMARY OF THE INVENTION

Embodiments of the present invention provide a method of filling a gap by using an HDP-CVD process that has an improved gap-fill characteristic and prevents a lung defect from occurring.

Embodiments of the present invention also provide a method of manufacturing an integrated circuit device by using an HDP-CVD process that has an improved gap-fill characteristic and prevents a lung defect from occurring.

According to one feature of the present invention, there is provided a method of filling a gap by using an HDP-CVD process wherein, when an insulating layer created by the HDP-CVD process that fills a gap contains fluorine groups, the insulating layer is plasma treated with a process gas that includes hydrogen. Since the hydrogen in the process gas and the fluorine group react with each other by the plasma treatment to produce hydrogen fluoride, the fluorine groups can be removed from the insulating layer. Thus, a lung defect does not occur in the insulating layer and when a rinsing or wet etch process is carried out, a dent in the insulating layer is avoided.

### BRIEF DESCRIPTION OF THE DRAWINGS

The above and other features and advantages of embodiments of the present invention will become more apparent by describing in detail exemplary embodiments thereof with reference to the attached drawings in which:

FIG. 1A is an SEM photograph of an integrated circuit device showing a lung defect.

FIG. 1B is a cross-sectional view of an integrated circuit device showing a dent.

FIGS. 2A through 2G are cross-sectional views of an integrated circuit device showing a method of manufacturing an integrated circuit device according to an embodiment of the present invention.

FIG. 3 is an SEM photograph of an integrated circuit device showing an HDP oxide layer filled according to an embodiment of the present invention.

FIG. 4 is a graph comparatively showing an FTIR spectrum of an HDP oxide layer filled according to the conventional technology and an FTIR spectrum of an HDP oxide layer filled according to another embodiment of the present invention.

FIGS. 5A through 5C are cross-sectional views of an integrated circuit device for showing a method of manufacturing an integrated circuit device according to yet another embodiment of the present invention.

### DETAILED DESCRIPTION OF THE PREFERRED EMBODIMENTS

Embodiments of the present invention will now be described more fully with reference to the accompanying drawings in which embodiments of the invention are shown. In the drawings, like reference numbers refer to like elements throughout and the sizes of elements may be exaggerated for clarity. Also, it will be understood that when an element such as a layer, region or substrate is referred to as being “on” or “onto” another element, it can be directly on the other element or intervening elements may also be present. Additionally, the layer, region or substrate could be partially within or partially embedded in another element.

A gap-fill method according to an embodiment of the present invention includes plasma treating an integrated circuit substrate with hydrogen in addition to an HDP-CVD process using a process gas containing a fluorine group, thereby preventing a lung defect from occurring. The gap-fill method can be applied to a process for filling a gap with a high aspect ratio, such as when depositing an HDP oxide layer in a device isolation trench or when depositing an insulating material in a space between gate line structures or bit line structures.

Other embodiments of the present invention will be described in detail by using a method of manufacturing a shallow trench isolation (STI) structure in an integrated circuit device as an example.

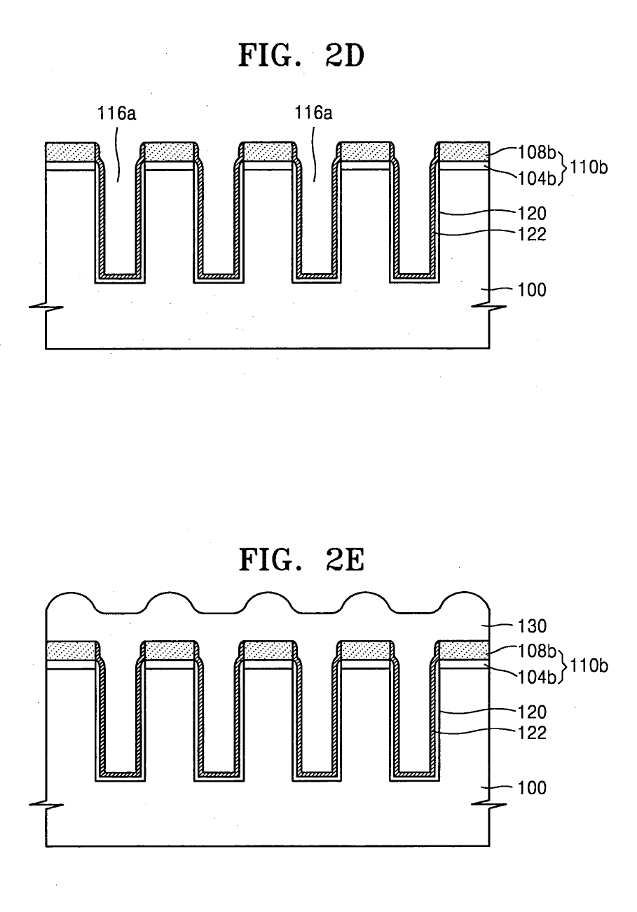

FIGS. 2A through 2G show a gap-fill method according to an embodiment of the present invention and the procedures of forming an STI structure in an integrated circuit device by the gap-fill method.

Referring to FIG. 2A, a first pad oxide layer 104 and a nitride layer 108 are successively formed on an integrated circuit substrate 100, for example, a silicon substrate. Then, an organic anti-reflection coating (ARC) (not shown) and a photoresist 112 are deposited on the nitride layer 108. The first pad oxide layer 104 is formed to decrease the stress between the substrate 100 and the nitride layer 108 and has a thickness of about 20 to 200 Å, preferably, about 100 Å. The nitride layer 108 is used as a hard mask in an etch process for forming a trench for an STI structure and is formed by depositing silicon nitride to a thickness of about 500 to 2,000 Å, preferably, 800 to 850 Å. A conventional method, for example, chemical vapor deposition (CVD) method, low pressure chemical vapor deposition (LPCVD) method or plasma enhancement chemical vapor deposition (PECVD) method may be used to deposit this layer.

Referring to FIG. 2B, a photoresist pattern 112a defining an active area is formed. Thereafter, the nitride layer 108 and the first pad oxide layer 104 are anisotropically dry etched using the photoresist pattern 112a as an etch mask. As a result, a pad mask 110a composed of a nitride pattern 108a and a first pad oxide layer pattern 104a is formed. When etching the nitride layer 108, a carbon fluoride type gas, such as a CₓF_{y} type gas or a CₐH_{b}F_{c} type gas may be used as an etch gas. Examples of the etch gas include CF₄, CHF₃, C₂F₆, C₄F₈, CH₂F₂, CH₃F, CH₄, C₂H₂, C₄F₆, or a mixture of the foregoing gases. Alternatively, an Ar gas may be used as an ambient gas.

Referring to FIG. 2C, the photoresist pattern 112a is removed using a conventional technique, for example, ashing with an oxygen plasma, and carrying out an organic strip process. Then, the exposed substrate 100 is anisotropically dry etched using the pad mask 110a as an etch mask. As a result, an STI trench 116 defining an active area is formed. The depth d of the STI trench 116 should be sufficient to isolate devices. Because the width of the STI trench 116 has to decrease to achieve high integration, the aspect ratio d:w has been continuously (and undesirably) increased.

Referring to FIG. 2D, a second pad oxide layer 120 and a liner nitride layer 122 are formed on the resulting substrate 100 with the STI trench 116 formed thereon. Due to the second pad oxide layer 120 and the liner nitride layer 122, the width of an STI trench 116a becomes narrower than the STI trench 116. The second pad oxide layer 120 is formed to treat damage caused to the silicon substrate 100 during the etch process for forming the STI trench 116a and to relieve stress due to the liner nitride layer 122. To this end, the second pad oxide layer 120 should be formed at least on the inner sidewall and the bottom of the trench 116. The second pad oxide layer 120 may be formed through a thermal-oxidation process or a CVD process. FIG. 2D shows the second pad oxide layer 120 which is formed through a thermal-oxidation process. As a result of the thermal-oxidation process, the thickness of the first pad oxide layer pattern 104b of the pad mask 110b may be slightly increased. The liner nitride layer 122 prevents the silicon substrate 100 from being oxidized due to the permeation of oxygen ions in subsequent thermal processes. The liner nitride layer 122 may be formed using a conventional CVD process. As a result of the formation process of the liner nitride layer 122, the thickness of the nitride pattern 108b of the pad mask 110b also may be increased slightly.

Referring to FIG. 2E, the STI trench 116a is filled with an HDP oxide layer 130. To fill the STI trench 116a with the HDP oxide layer, an HDP-CVD process is carried out according to the conventional technology. During the HDP-CVD process, a fluorine group-containing gas is used as a process gas. For example, silane and oxygen may be supplied into the HDP-CVD processing chamber as a deposition gas and nitrogen trifluoride is supplied into the processing chamber as a process gas. The supplied deposition gas and a part of nitrogen trifluoride are ionized by a plasma in the processing chamber.

During this process, the ionized deposition gas and nitrogen trifluoride are accelerated toward the surface of the integrated circuit substrate 100, since a bias power with high frequency is applied to a wafer chuck (not shown), for example, an electrostatic chuck, within the processing chamber. The accelerated deposition gas ions form a silicon oxide layer and the accelerated nitrogen trifluoride ions chemically etch the silicon oxide layer, producing a slight sputtering etch.

Thus, when the fluorine group-containing gas, such as nitrogen trifluoride, is used as a process gas, the gap-fill characteristic of the HDP oxide layer 130 can be improved. However, a plurality of silicon-fluorine bonds may be formed in the HDP oxide layer. As a result, a lung defect may be generated in the HDP oxide layer.

Referring to FIG. 2F, the deposited HDP oxide layer 130 is plasma treated, for example, with a hydrogen gas, or hydrogen and oxygen gases. The plasma treatment is carried out to remove a plurality of silicon-fluorine bonds formed in the HDP oxide layer 130. The plasma treatment may be carried out after completely filling the STI trench 116a by the HDP-CVD process or during the HDP-CVD process. Further, the plasma treatment and the HDP-CVD process may be carried out in situ. In this case, according to one embodiment of the present invention, the plasma treatment is performed at a pressure of approximately 1 Torr or less.

When both processes are carried out in situ, the plasma treatment may be carried out only once after the completion of the HDP-CVD process. Alternatively, before the formation of the HDP oxide layer 130 is completed, deposition of the HDP oxide layer through the HDP-CVD process and plasma treatment may be repeated two or more times.

In the plasma treatment according to an embodiment of present invention, a process gas containing hydrogen is preferably used. The hydrogen is used for removing fluorine groups present in the HDP oxide layer 130. Although the predetermined bias power is applied for the plasma treatment, hydrogen causes a little damage to the treated material layer by sputtering. The hydrogen flow rate may be in the range of about 100 to 1,000 sccm, more preferably, about 700 to 800 sccm. Moreover, oxygen may be added to the process gas to act as a carrier gas. The oxygen flow rate may be in the range of about 100 to 300 sccm, and more preferably may be as low as possible to minimize damage caused by the sputtering effect. However, other suitable process gases can be used as a carrier gas in addition to oxygen.

The intensity of a source power and a bias power applied during the plasma treatment is determined to shorten the processing time and increase productivity, and to avoid damaging the treated layer by sputtering. For example, the source power may be applied in the range of about 2,000 to 7,000 watts, more preferably, about 6,000 watts. The bias power may be applied in the range of about 1,000 to 4,000 watts, more preferably, about 2,000 watts.

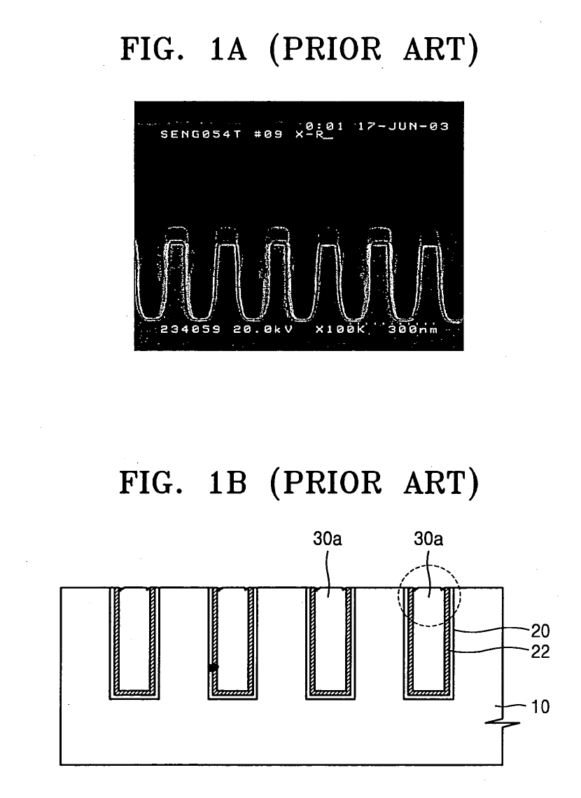

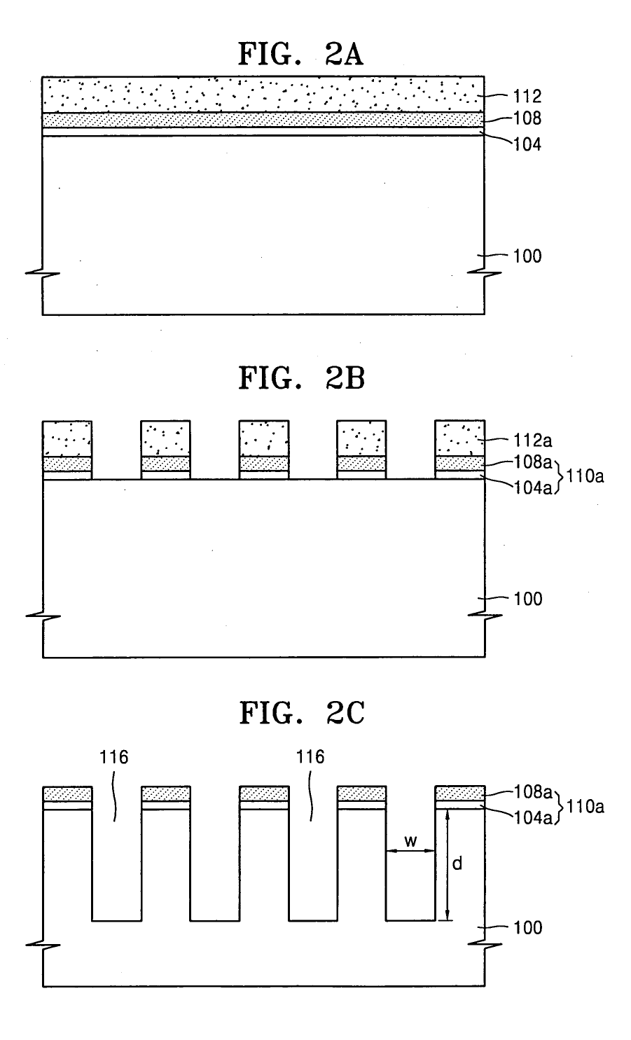

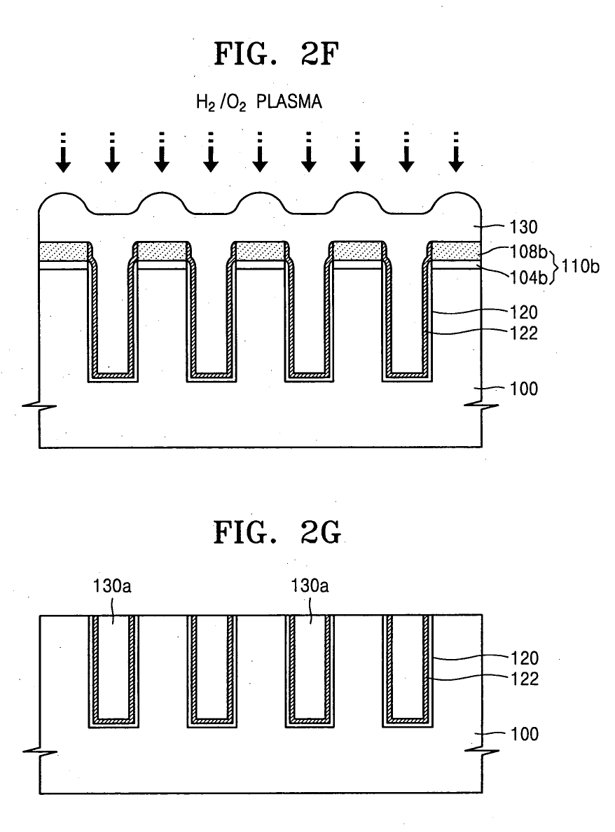

FIG. 3 shows an SEM photograph of an integrated circuit substrate, in which an HDP oxide layer is prepared according to the present embodiment. Referring to FIG. 3, there is no lung defect on the sidewall of the filled HDP oxide layer in contrast to the photograph shown in FIG. 1A. According to the present embodiment, hydrogen gas supplied in the plasma treatment destroys the silicon-fluorine bonds present in the HDP oxide layer, thus preventing a lung defect.

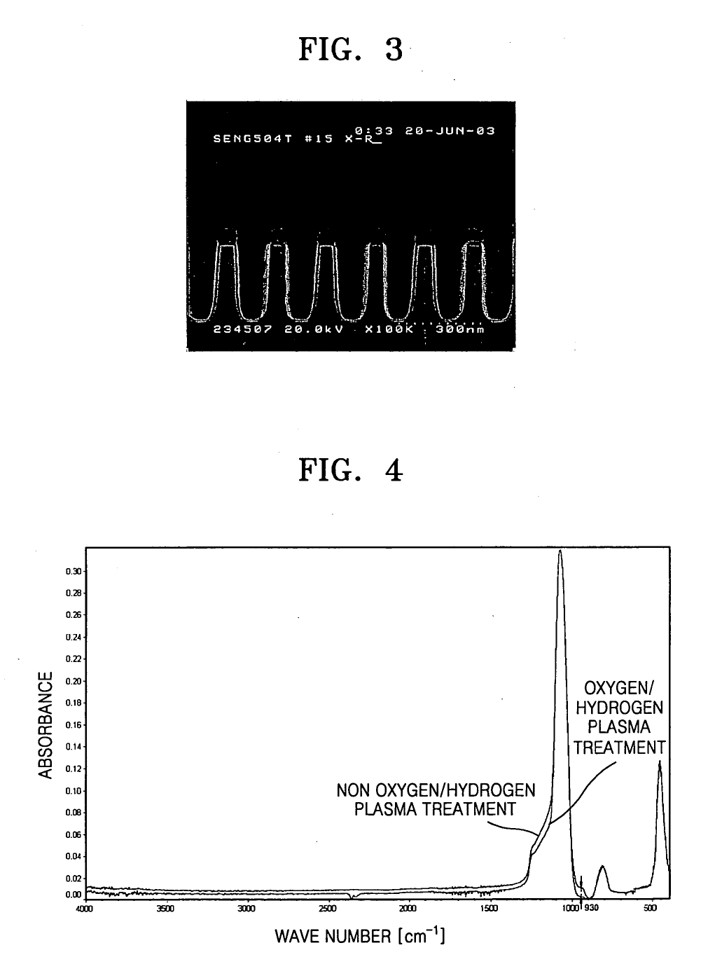

The absence of the silicon-fluorine bond in the HDP oxide layer can be verified through a Fourier Transform Infra-Red (FTIR) spectrum. FIG. 4 comparatively shows the FTIR spectrum of an HDP oxide layer filled according to an embodiment of the present invention and an FTIR spectrum of an HDP oxide layer prepared according to conventional technology. Referring to FIG. 4, the absorbance at a wave number of 930 cm−1 of the HDP oxide layer prepared according to an embodiment of the present invention is markedly lower than that of the HDP oxide layer prepared according to conventional technology, and is close to zero.

Referring to FIG. 2G, the HDP oxide layer 130 is planarized to substantially the same level as the top surface of the pad mask 110b. This planarization may be accomplished by a CMP process or etch back. During planarization the nitride layer pattern 108b is used as a planarization stop layer. During the CMP process, a slurry capable of more rapidly etching the HDP oxide layer 130 than the nitride layer pattern 108b is preferably selected. Thus, a slurry containing an abrasive such as ceria may be used.

Then, the pad mask 110b is removed to complete an STI structure 130a filled with the HDP oxide layer 130. The nitride layer pattern 108b in the pad mask 110b is removed by applying a phosphoric acid thereto. The pad oxide layer pattern 104b is removed by using diluted hydrogen fluoride, ammonium fluoride or buffered oxide etchant (BOE). Subsequently, a rinse process may be performed to remove impurities, such as particles or a natural oxide layer.

Next, an active element, such as a transistor, and a passive element, such as a capacitor, may be formed in the active area of the integrated circuit substrate 100 having a completed STI structure 130a through a common fabrication process, thereby completing an integrated circuit device.

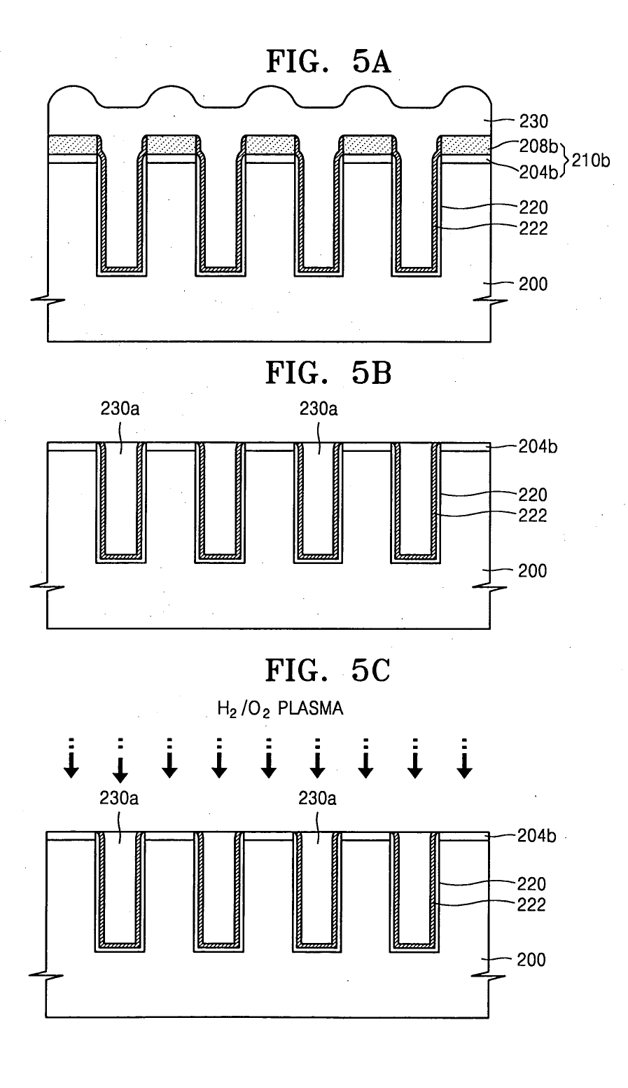

FIGS. 5A through 5C show a gap-fill method and a procedure of forming a shallow trench isolation structure of an integrated circuit device by using the gap-fill method. The present embodiment will be explained only as is necessary to show the differences from the previous embodiment.

FIG. 5A shows a cross section of an integrated circuit device, where an STI trench is filled with an HDP oxide layer 230. The integrated circuit device shown in FIG. 5A may be prepared according to the fabrication process disclosed in the above embodiment of the present invention. Referring to FIG. 5A, a trench for STI is formed on an integrated circuit substrate 200. A pad mask 210b composed of a first pad oxide layer pattern 204b and a pad nitride layer pattern 208b is formed on the active area of the integrated circuit substrate 200. A second pad oxide layer 220 and a liner nitride layer 222 are formed on the inner wall and the bottom of the trench. An HDP oxide layer 230 is deposited on the pad mask 210b and within the trench. The HDP oxide layer 230 is a layer deposited through the HDP-CVD process using nitrogen trifluoride as in the above embodiment of the present invention.

Referring to FIG. 5B, the HDP oxide layer 230 is planarized to substantially the same level as the top surface of the pad mask 210b. Planarization is accomplished by a CMP process or etch back. In the planarization, the nitride layer pattern 208b is used as a planarization stop layer. During the CMP process, a slurry capable of more rapidly etching the HDP oxide layer 230 than the nitride layer pattern 208b is preferably selected. Thus, a slurry containing an abrasive such as ceria may be used. The nitride layer pattern 208b is removed by applying a phosphoric acid.

Referring to FIG. 5C, the HDP oxide layer 230a is plasma treated with a hydrogen gas or hydrogen/oxygen gases. In the plasma treatment, the same processing conditions as in the above embodiment of the present invention can be used.

Subsequently, although not shown in FIGS. 5A through 5C, the pad oxide layer pattern 204b is removed using diluted hydrogen fluoride, ammonium fluoride or buffered oxide etchant (BOE). Then, a rinse process is performed to remove impurities, such as particles or a natural oxide layer. Next, an active element, such as a transistor, and a passive element, such as a capacitor may be formed in the active area of the integrated circuit substrate 200 having a completed STI structure 230a through a common fabrication process, thereby completing an integrated circuit device.

According to the above-described embodiments of the present invention, before performing a wet etch and/or a rinse process on an HDP oxide layer, plasma treatment with hydrogen and oxygen gases may be further performed. Since the plasma treatment removes silicon-fluorine bonds present in the HDP oxide layer, dents or grooves are not generated in the HDP oxide layer though a later wet etch and/or rinse process.

In another embodiment, to manufacture an integrated circuit device, a plurality of conductive line structures (not shown) are formed on an integrated circuit substrate (not shown). The areas between the conductive line structures are filled with a high density plasma oxide by performing an HDP-CVD process using a first process gas comprising a nitrogen trifluoride gas, a silane gas, and oxygen to form a high density plasma oxide layer. Then, the integrated circuit substrate is plasma treated with a second process gas comprising hydrogen or hydrogen/oxygen. In this embodiment, the conductive line structure may be a gate line structure, a bit line structure, or a metal wiring line.

According to embodiments of the present invention, when filling a gap with an HDP oxide, a gas containing fluorine groups is used as a process gas. Therefore, the gap-fill method according to embodiments of the present invention is less likely to produce voids compared to the gap-fill method through an HDP-CVD process using an inert gas and/or a hydrogen gas as a sputtering gas. Moreover, because plasma treatment using a hydrogen gas is further performed, the method can prevent the occurrence of a lung defect in the filled HDP oxide layer.

In addition, the plasma treatment and the HDP-CVD process can be performed in situ in the same HDP-CVD processing chamber, so that additional processing equipment is not needed.

While embodiments of the present invention has been particularly shown and described with reference to exemplary embodiments thereof, it will be understood by those of ordinary skill in the art that various changes in form and details may be made therein without departing from the spirit and scope of the present invention as defined by the following claims.

1. A gap filling method, the method comprising:
preparing a semiconductor substrate having gaps therein;
filling the gaps by performing a high density plasma-chemical vapor deposition (HDP-CVD) process using a first process gas comprising a gas containing an element from a fluorine group and a silane gas to form an insulating layer; and
plasma treating the insulating layer with a second process gas comprising hydrogen.

2. The gap filling method of claim 1, wherein the gas containing an element from the fluorine group is nitrogen trifluoride (NF₃).

3. The gap filling method of claim 1, wherein the second process gas further comprises oxygen (O₂).

4. The gap filling method of claim 3, wherein in the plasma treatment, a hydrogen flow rate is between approximately 100 and 1,000 sccm and an oxygen flow rate is between approximately 100 and 300 sccm.

5. The gap filling method of claim 3, wherein in the plasma treatment, a source power is between approximately 200 and 7,000 W and a bias power is between approximately 1000 and 4000 W.

6. The gap filling method of claim 1, wherein the HDP-CVD process and the plasma treatment are performed in situ.

7. The gap-filling method of claim 6, wherein the plasma treatment is performed only once after performing the HDP-CVD process.

8. The gap filling method of claim 6, wherein the HDP-CVD process and the plasma treatment are repeated two or more times.

9. The gap filling method of claim 6, wherein the plasma treatment is performed at a pressure of approximately 1 Torr or less.

10. The gap filling method of claim 9, which further comprises performing a predetermined process on the integrated circuit substrate outside the plasma processing chamber, between the HDP-CVD process and the plasma treatment.

11. The method of claim 1, wherein SiH₄ is used as the silane gas.

12. A method of manufacturing an integrated circuit device, the method comprising:
etching a predetermined area of an integrated circuit substrate to form a shallow trench isolation (STI) trench;
filling the trench with a high density plasma oxide by performing an HDP-CVD process using a first process gas comprising a gas containing an element from a fluorine group, a silane gas, and oxygen to form a high density plasma oxide layer; and
plasma treating the integrated circuit substrate with a second process gas comprising hydrogen.

13. The method of claim 12, wherein the trench filling and the plasma treatment are performed in situ.

14. The method of claim 13, wherein the trench filling and the plasma treatment are repeated two or more times.

15. The method of claim 13 which further comprises wet etching or rinsing the integrated circuit substrate after the plasma treatment.

16. A method of manufacturing an integrated circuit device, the method comprising:
etching a predetermined area of an integrated circuit device to form a trench;
filling the trench with a high density plasma oxide by performing an HDP-CVD process using a first process gas comprising a nitrogen trifluoride gas, a silane gas, and oxygen to form a high density plasma oxide layer; and
plasma treating the integrated circuit substrate with a second process gas comprising hydrogen in situ with the formation of the high density plasma oxide layer.

17. The method of claim 16, wherein in the plasma treatment, a hydrogen flow rate is between approximately 100 to 1,000 sccm and an oxygen flow rate is between approximately 100 and 300 sccm.

18. The method of claim 16, wherein in the plasma treatment, a source power is between approximately 2,000 and 7,000 W and a bias power is between approximately 1,000 and 4,000 W.

19. The method of claim 16, wherein the formation of the trench comprises:
forming a pad mask on the integrated circuit substrate; and
etching the integrated circuit substrate, using the pad mask as an etch mask, to form the trench.

20. The method of claim 16, which further comprises before filling the trench:
forming a second pad oxide layer on sidewalls and a bottom of the trench; and
forming a liner nitride layer on the second pad oxide layer.

21. The method of claim 20, which further comprises after the plasma treatment:
planarizing the high density plasma oxide layer; and
removing the liner nitride layer.

22. A method of manufacturing an integrated circuit device, the method comprising:
etching a predetermined area of an integrated circuit device to form a trench;
forming a second pad oxide layer on sidewalls and a bottom of the trench;
forming a liner nitride layer on the second pad oxide layer;
filling the trench with a high density plasma oxide by performing an HDP-CVD process using a first process gas comprising a nitrogen trifluoride gas, a silane gas, and oxygen to form a high density plasma oxide layer; and
plasma treating the integrated circuit substrate with a second process gas comprising hydrogen and oxygen.

23. The method of claim 22, which further comprises before the plasma treatment:
planarizing the high density plasma oxide layer; and removing the liner nitride layer.

24. A method of manufacturing an integrated circuit device, the method comprising:
forming a plurality of conductive line structures on an integrated circuit substrate;
filling areas between the conductive line structures with a high density plasma oxide and performing an HDP-CVD process using a first process gas comprising a nitrogen trifluoride gas, a silane gas, and oxygen to form a high density plasma oxide layer; and
plasma treating the integrated circuit substrate with a second process gas comprising hydrogen and oxygen.

25. The method of claim 24, wherein the conductive line structure is a gate line structure, a bit line structure, or a metal wiring line.

26. A gap filling method, the method comprising:
preparing a semiconductor substrate having gaps therein;
filling the gaps by performing a high density plasma-chemical vapor deposition (HDP-CVD) process using a first process gas to form an insulating layer; and
plasma treating the insulating layer with a second process gas comprising hydrogen.

27. The gap filling method of claim 26, wherein the first process gas comprises nitrogen trifluoride (NF₃).

28. The gap filling method of claim 26, wherein the second process gas further comprises oxygen (O₂).
